(19) United States
(12) Patent Application Publication
(10) Pub. No.: US 2016/0207770 A1
(43) Pub. Date: Jul. 21, 2016

(54) METHOD AND APPARATUS FOR PRODUCING CARBON NANOSTRUCTURES

(71) Applicants: Mikhail Rudolfovich PREDTECHENSKIY, (US); MCD TECHNOLOGIES S.A.R.L., Bertrange (LU)

(72) Inventor: Mikhail Rudolfovich Predtechenskiy, Novosibirsk (RU)

(21) Appl. No.: 14/655,783

(22) PCT Filed: Jan. 22, 2013
(86) PCT No.: PCT/RU2012/001053

§ 371 Date: Aug. 13, 2015

(51) Int. Cl. C01B 31/02; C30B 30/02; C30B 29/60; C30B 25/00; C30B 29/02

(52) U.S. Cl. CPC C01B 31/0206; C30B 25/00; C30B 29/02; C30B 29/602; C30B 30/02

(57) ABSTRACT

A system and method for producing carbon nano-structures. The proposed method allows for producing carbon nano-structures on a commercial scale, while reducing the degree of agglomeration and the influence of the walls of the reaction chamber on the process, as well as increasing control over the process of preparation of the nano-structures. A method for producing carbon nano-structure by decomposition of hydrocarbon gases in the reaction chamber in the presence of a catalyst includes preparing a working mixture, wherein the mixture includes nano-particles comprising a catalyst substance, a carrier gas and gaseous hydrocarbons; feeding the reaction mixture into the reaction chamber; discharging carbon nano-structures from the reaction chamber in a stream of gaseous products of hydrocarbon decomposition; and separating carbon nano-structures from gaseous products of hydrocarbon decomposition.

### CROSS-REFERENCE TO RELATED APPLICATION

This Application is a US National Phase of PCT/RU2012/001053 filed on Jan. 22, 2013.

### BACKGROUND OF THE INVENTION

1. Field of the Invention

The present invention relates to a method and apparatus for producing a carbon nano-structure by the catalytic decomposition of hydrocarbons.

2. Description of the Related Art

In recent years, carbon nanostructures attract more and more attention due to the possibility of obtaining new materials with unique properties. The nano-structures include fullerenes, carbon nano-tubes (CNT) and nano-wires, nano-diamonds, and carbon bulbous structures, graphene and others. Of these articles, nano-tubes come in a plurality of types that vary in structure, diameter, clarity, and a number of layers.

Various methods for producing carbon nano-structures are known, in particular, a method of thermal decomposition of hydrocarbons on the catalyst surface. For example, there is well-known Bayer method for producing carbon nano-tubes, see http://**.baytubes.com/. This method comprises decomposition of hydrocarbon gases in a reaction chamber with fluidized catalyst. This catalyst is prepared in advance and is in a form of particles comprising a substrate having an active catalytic substance deposited over its surface.

In the reaction chamber, the catalyst particles are distributed from the top of the chamber, and the gaseous substances (i.e., carbon sources) come from the bottom upwards, towards the catalyst nano-particles. Multiwall carbon nano-tubes grow on the substrate with the catalyst in the form of agglomerates. The agglomerates are removed from the reaction chamber during filtration process separating them from the gas phase.

The method described above provides production of nano-tubes on a large scale as a continuous process. However, production of multiwall nano-tubes in the form of the agglomerates is one of the shortcomings of the process. Such tubes have a low quality, and further complex dispersion of the agglomerates is required for obtaining a product suitable for applications.

A continuous process for the production of carbon nano-tubes is also proposed by Cambridge University Technical Services [UK Patent application number 2485339]. According to this method, the reaction chamber is filled with a gas mixture consisting of: a carbon source (e.g., methane CH4), a vapor of the catalyst substance (e.g., ferrocene Fe(C₅H₅)₂), and a retarding agent (e.g., carbon disulfide CS₂). The reaction chamber of the tubular shape is (for example a length of 2 m and the diameter of 0.08 m) is heated by the electrical heaters. The temperature in the reaction chamber is sufficient to decompose the catalyst substance.

At this temperature, the atoms of a transition metal are released (e.g., iron Fe), which leads to the growth of the catalyst nano-particles. At the same time, the retarding agent is decomposed releasing sulfur S atoms, resulting in a stunted growth of the catalyst particles. Preparation of the catalyst nano-particles of desired size is achieved by varying the ratio of the amount of the catalyst substance and the amount of the retarding agent, and by the selected temperature. Single-walled carbon nano-tubes are formed when the transition metal contacts the carbon source.

In this method, the catalyst nano-particles are formed directly inside the reaction chamber. Also, the nano-tubes grow on the surface of nano-particles of the catalyst inside the same chamber. It is obvious that such different by nature processes are difficult to control and optimize. Thus, controlling of the properties of the obtained carbon nano-structures becomes a problem.

For solving this problem, it is advisable to separate the processes of producing the catalyst nano-particles, preparation of the nano-particle mixture, the carrier gas, and hydrocarbons, heating of the reaction mixture and the final reaction of formation of carbon nanostructures. If the processes are divided during formation of catalyst nano-particles, there is an opportunity to control and optimize the growth of carbon nano-structures. Preparing a predetermined gas mixture at the required temperature allows for controlling the speed of mixing various gas components and facilitating the control of the entire process of producing carbon nano-structures.

It should be noted also that in the apparatus, where the carbon nano-structures grow on free catalyst nano-particles, only a relatively small volume of the reaction chamber is used. Firstly, it affects productivity. Secondly, due the small volume of the reaction chamber, an influence of its walls on the process cannot be avoided. The carbon nano-tubes grow on the walls filling the volume of the chamber, and changing the conditions of their formation. Deposition and growth of the tubes on the walls are due to the fact that during the typical residence times of the gaseous mixture in the reaction chamber (from a few seconds to tens of seconds), the atoms and molecules of the mixture repeatedly collide with the wall of the chamber, whereby there two different processes of formation of the nano-particles occur: one process is the formation of free carbon nano-particles in the gas phase on the surface of the catalyst nano-particle, and the other is the formation of nano-particles on the surface of the walls of the reaction chamber.

Obviously, the optimum conditions for the formation of nano-particles in the gas phase and on the wall surface are different, so the control of the process is complicated. On the other hand, the formation of nano-particles on the walls of the reaction chamber complicate withdrawal of the carbon nano-particles from the chamber resulting in lower reactor productivity and in increase in the cost of the final product.

A method of producing single-walled and multi-walled carbon nano-tubes based on the use of a hot filament as a source of catalyst nano-particles in the reaction chamber is disclosed in A. G. Nasibulin (“Development of technologies for the production of nano-scale powders and carbon nano-tubes by chemical vapor deposition.” Doctoral Dissertation for the degree of PHD in Sciences, Saint-Petersburg, Saint-Petersburg Technical University, Russia, 2011). The filament is made of a catalyst material: iron or nickel. By passing a current through it, a resistive heating takes place, whereby the catalyst is heated, and the surface of the incandescent filament evaporates the catalyst substance.

Then the vapor of the catalyst material is cooled and condensed resulting in the formation of the catalyst nano-particles. The obtained catalyst nano-particles are mixed with a carbon source in the reaction chamber. Carbon monoxide CO is used as the carbon source for the synthesis of single-walled carbon nano-tubes, and ethanol C₂H₆O or octanol C₈H₁₈O is used for producing multi-walled CNT. At an appropriate temperature, the carbon sources decompose, and carbon nano-structures grow on the surface of the catalyst nano-particle.

This method, like the one described above, has a low productivity due to the small size of the reaction chamber. In addition, heating of the working mixture occurs within the reaction chamber as it moves, and the process is difficult to control. Another method for producing carbon nano-tubes is disclosed in U.S. Pat. No. 8,137,653. According to this method, the reaction chamber is maintained at 500-1200° C., and a catalyst material in a vapor form is generated. The vapor is then condensed in the reaction chamber to form free catalyst nano-particles, on the surface of which carbon nanostructures are formed by the decomposition of gaseous hydrocarbons.

The vapor of the substance containing the catalyst is obtained by an electric arc discharge, which is formed between two electrodes, at least one of which is in the shape of an open container located in the reaction chamber and filled with the catalyst metal. The metal melts under the impact of the arc discharge, so the electrode is at least in the partially melted state and serves as a source of the vapor of the material containing the catalyst.

In this method, the formation of the vapor of the substance containing the catalyst and formation of catalyst nano-particles occurs directly in the reaction chamber. In the same chamber, the formation of carbon nano-structures takes place. As mentioned above, the presence of such different by nature processes in one container complicates control and optimization of the processes. Consequently, a problem of controlling the properties of obtained carbon nano-structures exists.

Thus, the existing conventional methods for catalytic producing of carbon nano-tubes have a number of disadvantages discussed above. Therefore, it is desired to eliminate the drawbacks of known catalytic methods for producing carbon nano-structures, as well as to develop a relatively inexpensive method for producing carbon nano-structures on a large scale with a high quality, to meet the needs of a variety of technological applications.

### SUMMARY OF THE INVENTION

The present invention provides method and apparatus for producing carbon nano-structure by the catalytic decomposition of hydrocarbons that substantially obviates one or several of the disadvantages of the related art.

In one aspect of the invention, a method and system for producing carbon nano-structures are provided. The proposed method allows for producing carbon nano-structures on a commercial scale, while reducing the degree of agglomeration and the influence of the walls of the reaction chamber on the process, as well as increasing control over the process of preparation of the nano-structures.

According to an exemplary embodiment, a method for producing carbon nano-structure by decomposition of hydrocarbon gases in the reaction chamber in the presence of a catalyst at a temperature of 600-1200° C. comprises the following steps:

(a) preparing a working mixture having a temperature of 400-1400° C., wherein the mixture includes nano-particles comprising a catalyst substance, a carrier gas and gaseous hydrocarbons. The nano-particles of the catalyst substance have an average size of less than 100 nm (preferably 1-40 nm), and the nano-particles are formed by condensation of the vapor or decomposition products of chemical compounds containing the catalyst material; (b) feeding the reaction mixture into the reaction chamber having a volume of at least 0.03 m³ and having the distance between the opposite walls or the diameter of at least 0.1 m; (c) discharging carbon nano-structures from the reaction chamber in a stream of gaseous products of hydrocarbon decomposition; (d) separating carbon nano-structures from gaseous products of hydrocarbon decomposition (for example, by filtration).

Additional features and advantages of the invention will be set forth in the description that follows, and in part will be apparent from the description, or may be learned by practice of the invention. The advantages of the invention will be realized and attained by the structure particularly pointed out in the written description and claims hereof as well as the appended drawings.

It is to be understood that both the foregoing general description and the following detailed description are exemplary and explanatory and are intended to provide further explanation of the invention as claimed.

### BRIEF DESCRIPTION OF THE ATTACHED FIGURES

The accompanying drawings, which are included to provide a further understanding of the invention and are incorporated in and constitute a part of this specification, illustrate embodiments of the invention and, together with the description, serve to explain the principles of the invention.

In the drawings:

FIG. 1 illustrates a diagram of an apparatus, in accordance with the exemplary embodiment;

FIG. 2 illustrates a first embodiment of a system for preparing the working mixture;

FIG. 3 illustrates the second embodiment a system for preparing the working mixture;

FIG. 4 illustrates a third embodiment of a system for preparing the working mixture;

FIG. 5 illustrates a fourth embodiment of a system for preparing the working mixture;

FIG. 6 illustrates a fifth embodiment of a system for preparing the working mixture;

FIG. 7 illustrates a picture of a nano-material obtained by the described method.

### DETAILED DESCRIPTION OF THE PREFERRED EMBODIMENTS

Reference will now be made in detail to the preferred embodiments of the present invention, examples of which are illustrated in the accompanying drawings.

According to an exemplary embodiment, a method and system for producing carbon nano-structures are provided. The proposed method allows for producing carbon nano-structures on a commercial scale, while reducing the degree of agglomeration and the influence of the walls of the reaction chamber on the process, as well as increasing control over the process of preparation of the nano-structures.

According to the exemplary embodiment, the method for producing carbon nano-structure by decomposition of hydrocarbon gases in the reaction chamber in the presence of a catalyst at a temperature of 600-1200° C. comprises the following steps:

(a) preparing a working mixture having a temperature of 400-1400° C., wherein the mixture includes nano-particles comprising a catalyst substance, a carrier gas and gaseous hydrocarbons. The nano-particles of the catalyst substance have an average size of less than 100 nm (preferably 1-40 nm), and the nano-particles are formed by condensation of the vapor or decomposition products of chemical compounds containing the catalyst material;

(b) feeding the reaction mixture into the reaction chamber having a volume of at least 0.03 m³ and having the distance between the opposite walls or the diameter of at least 0.1 m;

(c) discharging carbon nano-structures from the reaction chamber in a stream of gaseous products of hydrocarbon decomposition;

(d) separating carbon nano-structures from gaseous products of hydrocarbon decomposition (for example, by filtration).

The feed rate of the working mixture in the reaction chamber is maintained so that the residence time of the mixture in the reaction chamber is 0.05-100 min.

For this method, gaseous hydrocarbons are preferably selected from natural gas, methane, ethane, propane, butane, pentane, hexane, ethylene, propylene, aliphatic hydrocarbons, and hydrocarbons in which the number of carbon atoms ranges from 1 to 10, mono-, or bicyclical aromatic hydrocarbons with fused or insulated rings and olefins CₓH₂ₓ, wherein x is 2, 3, or 4, other gaseous hydrocarbon, hydrocarbons with a high saturated vapor pressure, ethyl alcohol, a vapor of anthracene or anthracene oil, or a mixture of two, three or more thereof.

The catalyst substance for this method is selected from the following groups: Group 5 transition metal, Group 6B transition metal, Group 8 transition metal, preferably iron, or a mixture of two, three, or more elements belonging to the transition metals. For this method a carrier gas, preferably selected from the group of an inert gas or hydrogen, nitrogen, ammonia, a hydrocarbon, alcohol vapor or a mixture of two, three or more thereof. The nano-particles containing the catalyst substance can include nucleon of carbon nano-structures.

Vapors containing catalyst substance can be prepared in an evaporation chamber in an atmosphere of a flow gas by electrical explosion of a wire comprising the catalyst substance, when an electric current impulse passes through it. The current density should be sufficient to convert the wire material into the vapor phase without the formation of liquid droplets. It occurs at a current density of 10⁴-10⁷ A/mm². A typical diameter of the wire can be selected in the range of 0.02 mm-0.5 mm, but it is not limited by these values. Optimal wire diameters are in the range of 0.05-0.2 mm.

The flow gas is preferably selected from an inert gas, a hydrocarbon, nitrogen, alcohol vapor, and a mixture of two, three or more thereof. In one of the embodiments, in the step of producing a working mixture, the flow gas with the nano-particles containing the catalyst substance can be mixed with gaseous hydrocarbons and then with a carrier gas. In this case, the flow gas can be either an inert gas or nitrogen, or hydrocarbon, or a mixture thereof. In another embodiment, in the step of producing the working mixture, the flow gas with the nano-particles containing the catalyst substance can be mixed with a carrier gas and further with gaseous hydrocarbons. In this case, the flow gas is either an inert gas or nitrogen.

In the step of producing a working mixture, the flow gas with the nano-particles containing the catalyst substance can be mixed with a carrier gas. In this case, the flow gas is a gaseous hydrocarbon or a hydrocarbon mixture with an inert gas or nitrogen. Vapors containing a catalyst substance can be prepared in the evaporation chamber by an electric arc discharge formed between two electrodes, at least one of which contains a catalyst substance. This electrode can be shaped as an open container filled with a metal containing catalyst substance and at least partially melted.

The electrode comprising a catalyst substance is melted and vaporized under the action of the arc discharge. The resulting vapor condenses to form nano-particles containing a catalyst substance. The material of the other electrode can be, for example, graphite. In the step of preparing a working mixture, the carrier gas is passed through the evaporation chamber where it captures nano-particles comprising the catalyst substance, whereupon it is mixed with the gaseous hydrocarbons.

A vapor containing catalyst substance can be prepared in the evaporation chamber by electric arc discharge that is formed between the two electrodes, each of which is configured as an open container filled with metal containing catalyst substance, and at least partially melted. The chamber is divided into two parts having each of the electrodes located in a separate part, and the parts are interconnected by a discharge channel, into which a plasma forming gas is supplied as a vortex-type flow. The plasma forming gas is selected from the group of: a hydrocarbon gas, an inert gas, hydrogen, nitrogen, ammonia, and a mixture of at least two thereof. In the step of preparing a working mixture, the carrier gas is passed through the evaporation chamber, where it captures nano-particles comprising the catalyst substance, whereupon it is mixed with the gaseous hydrocarbons.

A liquid or solid organo-metallic compound can be used as a source of the catalyst substance. The liquid organo-metallic compound is preferably iron pentacarbonyl, but other suitable substances can be used. The solid metal compound is preferably selected from the group of: ferrocene, nikelecene, cobaltocene. Other suitable substances can be used as well. In case when the organo-metallic compound is a liquid, in the step of preparing a working mixture, the liquid organo-metallic compound is vaporized by heating it at least to the boiling point, and the obtained vapor is heated to at least the temperature of decomposition by mixing it with a carrier gas preheated to a temperature of 400-1400° C., or by heating them by a heater.

In case when the organo-metallic compound is solid, in the step of preparing a working mixture, the organo-metallic compound preliminarily is melted by heating it to at least its melting temperature, and then evaporated by heating to at least the boiling point, and the resulting vapors are heated at least to the temperature of their decomposition. Heating up to the decomposition temperature can be achieved by mixing the vapor with the carrier gas preheated to a temperature of 400-1400° C., or by heating them with a heater.

The vapors of a solid organo-metallic compound also can be prepared by spraying a fine powder of the compound with a spraying gas, and heating the powder-gas mixture to the boiling point of the compound. Then, the resulting vapor is heated to the decomposition temperature of the organo-metallic compound. If the compound is able to decompose directly from the solid state, the decomposing of the organo-metallic compound occurs from the solid powder phase without evaporation. Heating up to the decomposition temperature can be provided by traditional heaters or by mixing with hot carrier gas preheated to a temperature of 400-1400° C.

In the powder-gas mixture or in a mixture of gas and vapors of the organo-metallic compound, gaseous hydrocarbons can be introduced-e.g., thiophene or other sulfur-containing compounds or steam, in order to optimize the process of decomposition of the organo-metallic compound and to obtain an optimum size of the catalyst nano-particles. For reducing the load on the heater, the gaseous hydrocarbons can be preheated to a temperature of 400° C. and above.

The carrier gas, after mixing with the vapor of the organo-metallic compound, is further mixed with gaseous hydrocarbons for producing the working mixture. Carbon nano-structures deposited or formed on the walls of the reaction chamber can be removed by mechanical means, for example, by a movably mounted scraper ring located within the chamber, which removes carbon nanostructure from the walls during its movement along the axis of the chamber.

If necessary, the working mixture is further heated before being fed into the reaction chamber. The proposed apparatus for producing carbon nano-structure can be used for implementation of the described method. The apparatus comprises a reaction chamber provided with an inlet and outlet for a working mixture and with an outlet for the products of hydrocarbon decomposition, a container for preparing the working mixture which comprises nano-particles containing the catalyst substance, a carrier gas, hydrocarbon gases, and a filter for separating carbon nano-structures from the gaseous products of decomposition of the hydrocarbons, wherein the reaction chamber has a volume of at least 0.03 m³ and the distance between the opposing walls of the reaction chamber or the diameter of at least 0.1 m.

A container for preparing the working mixture can include an evaporation chamber provided with a source of electrical impulses. The chamber contains a fine metal wire comprising the catalyst substance. The wire is configured to explode when the electric impulse passes through it. The density of the electric current is in the range of 10⁴-10⁷ A/mm², and the chamber is provided with an input for the flow gas and an outlet for its mixture with nano-particles containing the catalyst substance, and a unit for mixing the resulting mixture with gaseous hydrocarbons or with the carrier gas.

In another embodiment, a container for the working mixture can be implemented as an evaporation chamber with two electrodes, one of which is made of a material containing a catalyst substance that is able to melt and vaporize under the impact of an electric arc discharge between the electrodes. The chamber is provided with an input for a carrier gas and an outlet for the mixture of the carrier gas and the nano-particles containing the catalyst substance, and also a unit for mixing the resulting mixture of the carrier gas with the nano-particles and gaseous hydrocarbons. The electrode, which is made of a material comprising a catalyst substance, is able to melt and can take the shape of an open container filled with the metal.

In yet another embodiment, a container for preparing the working mixture can be implemented as an evaporation chamber comprising two electrodes, each electrode is made in a shape of an open container filled with a metal containing the catalyst substance and is configured to melt and vaporize under the impact of an electric arc discharge between the electrodes. The chamber is divided into two parts, and each electrode is located in a separate part.

The parts of the chamber are interconnected by a discharge channel, which is provided with an inlet for a plasma forming gas configured in such a manner that the plasma forming gas enters it in a vortex flow. The channel is provided with an inlet for the carrier gas and an outlet for the carrier gas mixture with nano-particles containing the catalyst substance and a unit for mixing the resulting mixture of the carrier gas with the nano-particles and gaseous hydrocarbons.

According to another exemplary embodiment, a container for preparing the working mixture can include an evaporation channel and decomposition channel of the liquid organo-metallic compound with successive heaters, an inlet for hot carrier gas with the nano-particles containing the catalyst substance, and a unit for mixing them with gaseous hydrocarbons.

The same container for preparing the working mixture for a solid organo-metallic compound further is provided with a melting chamber for the organo-metallic compound. The chamber is connected to the evaporation channel through a dispenser. According to one exemplary embodiment, a unit for preparing the working mixture can be implemented as a container for the powder of the organo-metallic compound connected to a powder spray channel through the dispenser, which in turn is connected to the evaporation channel for the powder of the organo-metallic compound connected to the channel of decomposition of the organo-metallic substance. The channel of decomposition of the organo-metallic substance is provided with a carrier gas inlet and an outlet for the carrier gas with nano-particles containing a catalyst substance. The outlet is connected to the mixing unit, which also has an inlet for hydrocarbons and an outlet for the working mixture.

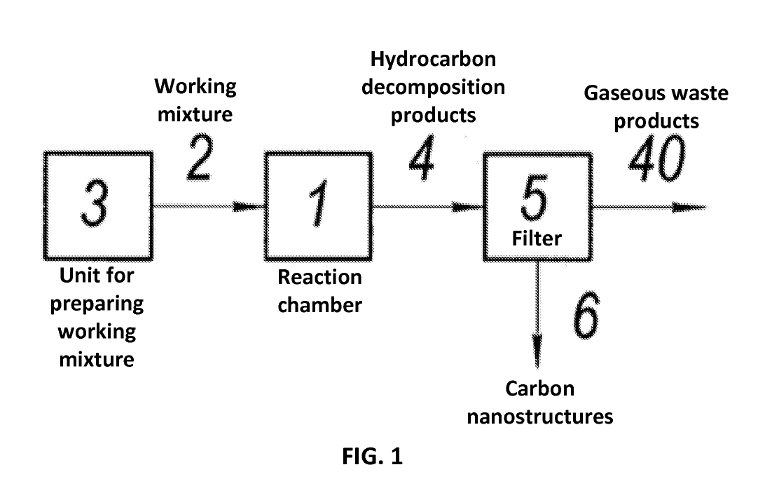

The reaction chamber can also be provided with a mechanism for cleaning the walls of nano-structures deposited or formed on the walls of the reaction chamber. FIG. 1 illustrates a general diagram of an apparatus for producing carbon nano-structures by implementing the described method. In FIG. 1, unit 1 is the reaction chamber, 2 is the working mixture, 3 is the unit for preparing the working mixture, 4 are products of hydrocarbon decomposition, 5 is a filter, 6 is carbon nano-structures and 40 is gaseous wastes.

The process is carried out as follows:

The unit 3 for preparing the working mixture mixes the preformed flows that the resulting mixture comprises the carrier gas, the nano-particles comprising the catalyst substance, and gaseous hydrocarbons. The temperature of the mixture is maintained in the range of 400-1400° C. In case the working mixture in the container for preparing the working mixture 3 has a lower temperature, it is further heated. The nano-particles included in the working mixture and comprising the catalyst substance have an average size of less than 100 nm (preferably 1-40 nm) and are formed by condensation of a vapor, or they can be products of decomposition of chemical compounds containing the catalyst substance.

The prepared working mixture 2 has at the above temperature is fed into the reaction chamber 1 having a volume of not less than 0.03 m³ and the distance between the opposite walls of the reaction chamber, or the diameter, of at least 0.1 m. The working mixture is fed at such a rate that the time of its presence in the chamber is in the range of 0.05-100 min. The preferred time of the presence in the chamber is about 10 seconds.

For reducing the influence of the chamber walls on the formation of carbon nanostructures, it is required to minimize the number of collisions of molecules with the walls. This is achieved by increasing the size of the reaction chamber to such values that most of the gas particles during their stay in the chamber have no time to contact the wall. This, in turn, is achieved under the condition that the distance between the closest walls of the chamber, or the diameter (d), is at least substantially larger than the typical diffusion length (L) of the mixture molecules during their residence time in the reaction chamber (t), i.e., d >L.

The value of L can be estimated by the well-known formula L=(D·t)^{0.5}, where D is the diffusion coefficient. The value of the diffusion coefficient for the gas at a temperature in the reaction chamber of about 900° C. is D=10-4 m²/s. Then, for a residence time of the gas mixture t=10 s the obtained diffusion length L=10⁻¹ m, or a value of the distance between the opposing walls of the reaction chamber, or its diameter should be at least 0.1 m. Desirably, this distance, or the diameter of the chamber, is not less than 0.3 m. Accordingly, if there is such minimum distance between the walls, or such chamber diameter, its volume must be not less than 0.03 m³.

In the reaction chamber 1 at a temperature of 600-1200° C., the decomposition of gaseous hydrocarbons of the working mixture 2 occurs leading to formation of free carbon, which is formed into carbon nanostructures, such as carbon nano-tubes growing on the surface of the catalyst nano-particles. The formed nano-structures with the gas consisting of the hydrocarbon decomposition products and residues of the carrier gas 4 are withdrawn from the reaction chamber.

The gaseous hydrocarbons used in the method, advantageously, belong to the group comprising: methane, ethane, propane, butane, pentane, hexane, ethylene, propylene, aliphatic hydrocarbons, hydrocarbons, in which the number of carbon atoms is between 1 and 10 (i.e., 1, 2, 3, 4, 5, 6, 7, 8, 9 or 10), mono-or bi-cyclic aromatic hydrocarbons and olefins CₓH₂ (where x is 2, 3 or 4), vapor of anthracene or anthracene oil, other gaseous hydrocarbons, a hydrocarbon having a high vapor pressure, ethyl alcohol and a mixture thereof. The gaseous hydrocarbons are the raw material for the production of carbon nano-structures.

For isolating the carbon nano-structures as end product 6, it is required to separate the solid phase from the gaseous phase 40 passing the products of hydrocarbon decomposition through a filter 5 or a cyclone, or another equivalent means. The products of hydrocarbon decomposition can be pre-cooled before separating the solid phase from the gas phase.

It is required for the proposed method that free nano-particles containing the catalyst substance are fed into the reaction chamber. These particles can be of a compound of the catalyst substance with other chemicals or a pure substance, such as iron. The nano-particles are fed into the reaction chamber inside the flow of the working mixture. The nano-particles containing the catalyst substance have an average size of less than 100 nm, preferably 1-40 nm. Such nano-particles are prepared during the step of preparation of the working mixture by condensing vapors or products of decomposition of the chemical compounds containing the catalyst substance. The vapors or decomposition products containing the catalyst substance are obtained in the step of preparation of the working mixture using various devices.

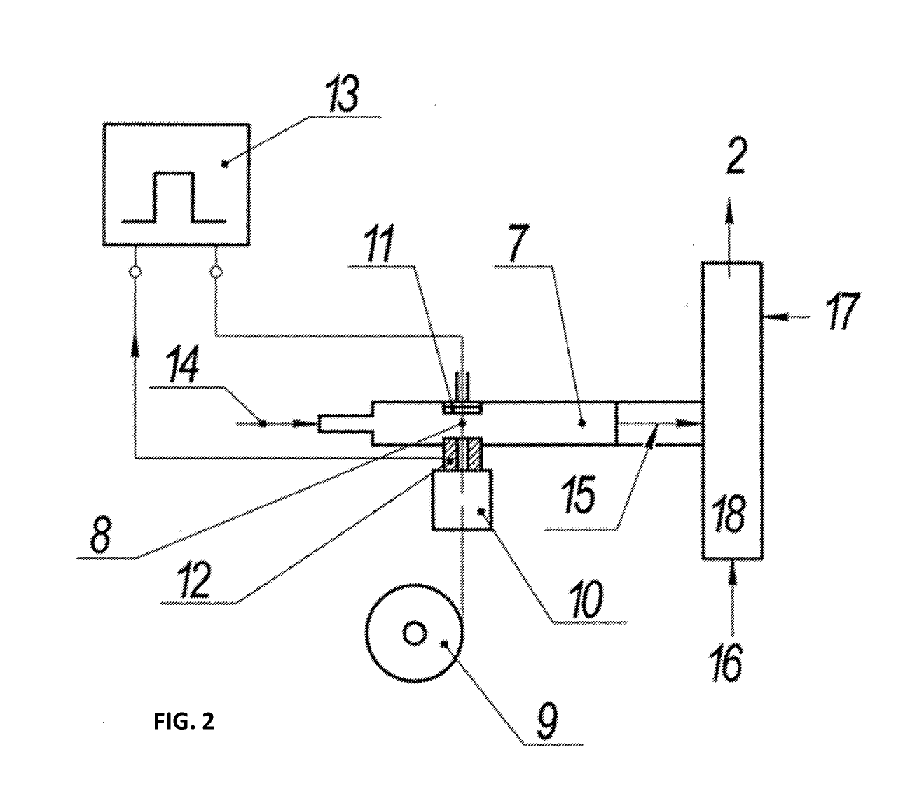

FIG. 2 illustrates a unit for preparing the working mixture according to a first embodiment, wherein: 2 is the working mixture, 7 is the evaporation chamber, 8 is a wire, 9 is a wire coils, 10 is the means for feeding the wire, 11 is a high-voltage electrode, 12 is the electrode, 13 is a generator of high voltage pulses, 14 is a gas flow, 15 is a flow gas with the nano-particles of the catalyst substance, 16 is a carrier gas, 17 is gaseous hydrocarbons, 18 is a mixing unit.

In the unit for the preparation of the working mixture 2 nano-particles comprising the catalyst substance are obtained by electric explosion of the thin metal wire 8 having the catalyst substance when a current pulse passes through it. The density of electric current flowing through the wire during the electric explosion is 10⁴ - 10⁷ A/mm². The source of the current pulses is a high-voltage pulse generator 13. The wire can be made entirely of a catalytic material, or can comprise a mixture of a catalyst and other substances.

The wire is located in the evaporation chamber 7. It is wound onto the roll 9, which is controlled by a means for feeding the wire 10. The exploding part of the wire is placed between the high voltage electrode 11 and the other electrode 12. When an impulse from the high voltage pulse generator is applied to the electrodes, the wire explodes producing a vapor containing the catalyst substance. Simultaneously, the flow gas 14 is fed into the vaporization chamber. In this atmosphere, the nano-particles are formed by condensation of the vapor of the substance containing the catalyst.

The flow gas with the nano-particles of the substance comprising the catalyst 15 is passed from the evaporation chamber into the mixing unit 18 where it is first mixed with a carrier gas 16. Further, the carrier gas with the nano-particles containing the catalyst substance is mixed with gaseous hydrocarbons 17 that can be preheated to a temperature of 400° C. or higher. As a result, in the mixing unit 18, all the ingredients and the finished working mixture 2 flow into the reaction chamber. In another embodiment for preparing the working mixture, the flow gas with the nano-particle of the catalyst substance 15 is first mixed with gaseous hydrocarbons, and then with the carrier gas.

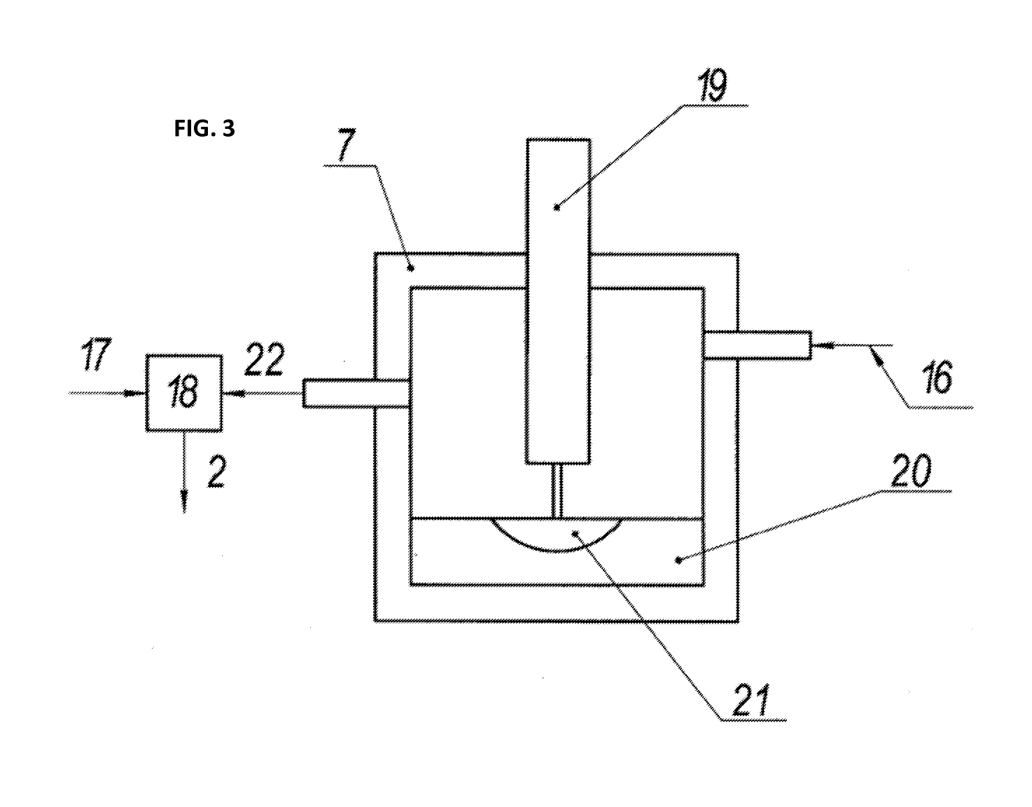

FIG. 3 illustrates a unit for preparing the working mixture, in accordance with the second embodiment, wherein:

2 is the working mixture, 7 is the evaporation chamber, 16 is the carrier gas, 17 is gaseous hydrocarbons, 18 is the mixing unit, 19 is the solid electrode, 20 is the partially melted electrode, 21 is the melted part of the electrode, 22 is the carrier gas with nano-particles containing the catalyst substance. It this embodiment for preparation of the working mixture, the nano-particles comprising the catalyst substance are obtained using an electric arc discharge between the two electrodes 19 and 20. The electrode 20 is configured in the shape of a container filled with a material capable of melting under the impact of the electric arc discharge and comprising the catalyst substance.

Both electrodes are placed in the evaporation chamber 7 opposite of each other. When an electric discharge between the electrodes occurs, the electrode 20 begins to melt forming a vapor of the catalyst substance. The vapor enters the volume of the evaporation chamber. Simultaneously, the carrier gas is supplied to the evaporation chamber 16. In the carrier gas, the vapors of the catalyst substance condensate forming nano-particles comprising the catalyst substance.

The carrier gas with nano-particles containing the catalyst 22 substance is discharged from the evaporation chamber and fed into the mixing unit 18. The mixing unit is also fed gaseous hydrocarbons 17 that can be preheated to a temperature not exceeding the temperature of pyrolysis, preferably not less than 400° C. The mixture obtained in the mixing unit is working with a mixture 2 and is fed into the reaction chamber.

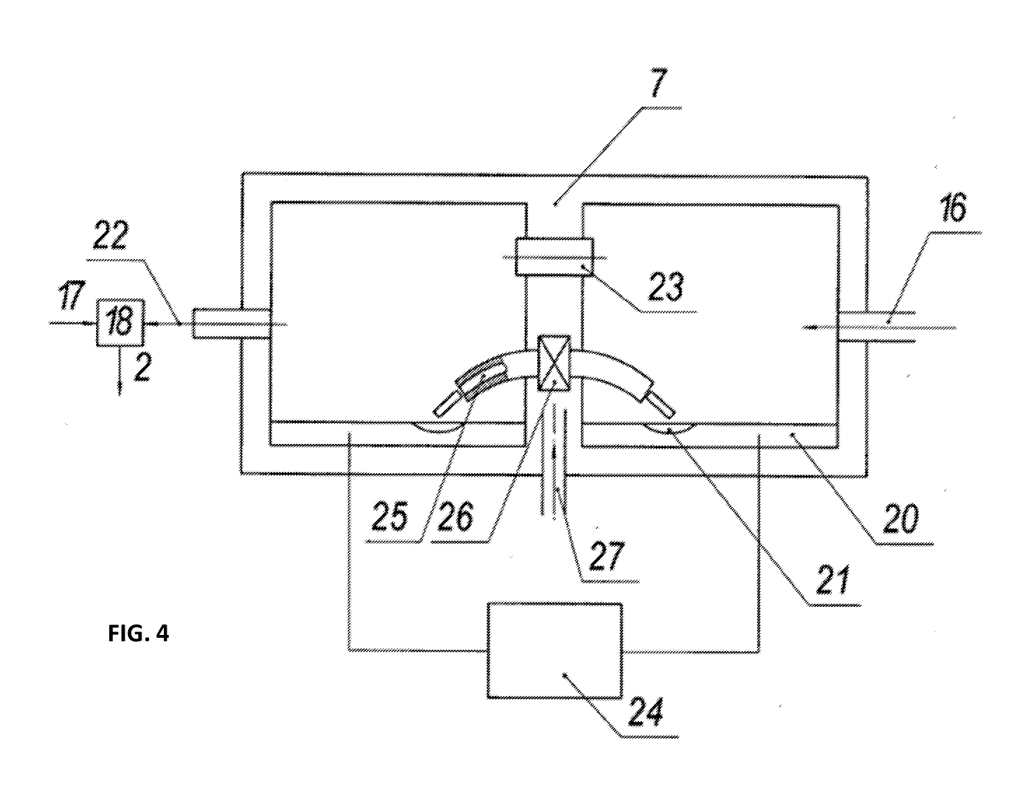

FIG. 4 illustrates a unit for preparing the working mixture in accordance to the third embodiment, wherein:

2 is the working mixture, 7 is the evaporation chamber, 16 is the carrier gas, 17 is gaseous hydrocarbons, 18 is the mixing unit, 20 is the partially melted electrode, 21 is the melted portion of the electrode, 22 is the carrier gas with the nano-particles, 23 is the gas channel between the parts of the evaporation chamber, 24 is the power source, 25 is the discharge channel, 26 is the vortex chamber, 27 is plasma forming gas.

In this unit for preparing the working mixture, nano-particles comprising a catalyst substance are obtained by an electrical arc discharge between the two partially melted electrodes 20. The evaporation chamber 7 comprises two electrodes, each shaped as a container filled with a material containing the catalyst substance, or it can be made of the catalyst substance, e.g., iron.

The unit comprises two electrodes 20 located in the separate parts of the evaporation chamber 7. Both electrodes are implemented in a shape of an open container filled with the material comprising the catalyst substance, or made of the catalyst. Both electrodes are able to melt and vaporize under the impact of an electric arc discharge. Two parts of the evaporation chamber 7 are interconnected by the gas channel 23 and the discharge channel 25, which is fed by the plasma forming gas 27 to maintain the electrical arc in the channel. The discharge channel has an inlet formed in the center of the channel, and the plasma forming gas 27 is fed through the inlet to form a vortex movement of the gas. This allows for obtaining a stable electric arc discharge in the discharge channel.

The plasma-forming gas is introduced into the discharge channel in a form of the vortex flow using standard and well known methods. For example, the plasma-forming gas can be introduced into the discharge channel tangentially to form a vortex flow stabilizing the arc discharge. The plasma-forming gas can contain a gaseous hydrocarbon or an inert gas, and one or more gases from the group of nitrogen, hydrogen, and ammonia. The evaporation chamber is provided with the inlet 16 for a carrier gas, into which the substance containing the catalyst evaporates, and an outlet for the carrier gas with the catalyst substance nano-particles 22 contained in it.

Both electrodes can be made entirely of the catalyst substance or can comprise a mixture of the catalyst and other substances. The electrode can comprise more than 20%, more than 30%, more than 40%, more than 50%, more than 60%, more than 70%, more than 80%, more than 90%, more than 95% and so on up to almost of 100% catalyst substance. Vapors containing the catalyst substance obtained by evaporation of the electrodes in the electric discharge condense in the atmosphere of the carrier gas.

The carrier gas 22 with nano-particles from the evaporation chamber 7 enters into the mixing unit 18 where it is mixed with gaseous hydrocarbons previously heated at least up to 400° C. It should be noted that gaseous hydrocarbons can have a lower temperature, or even not be heated at all. However, when the hydrocarbons are preheated, the process of preparation of the working mixture takes less time. The prepared working mixture 2 is fed into the reaction chamber.

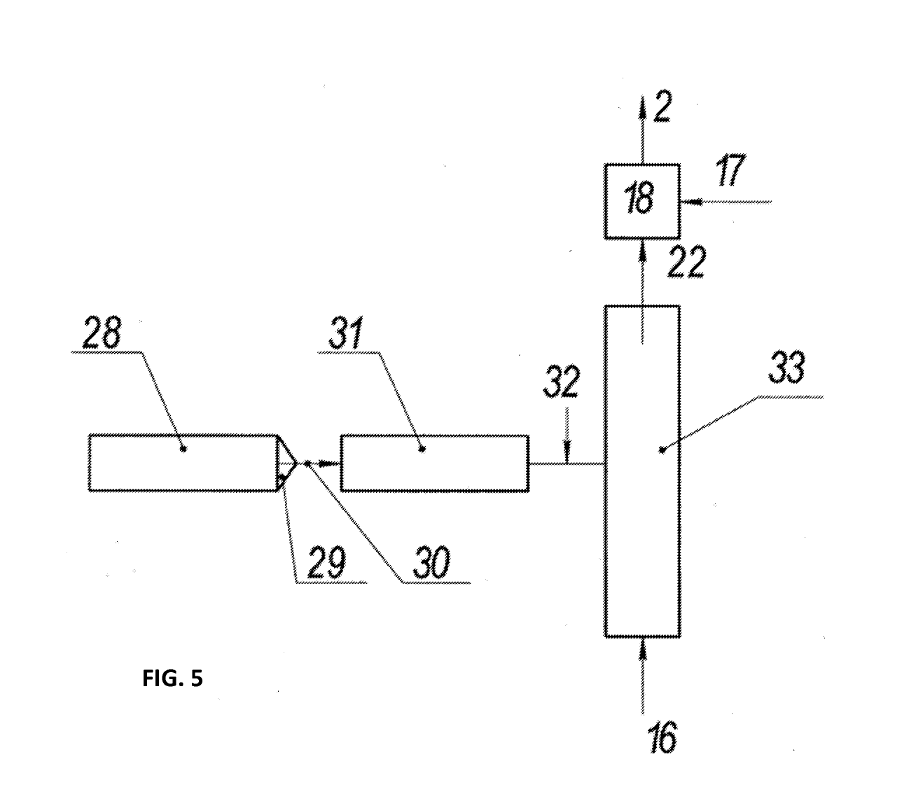

FIG. 5 illustrates a unit for preparing the working mixture in accordance with another exemplary embodiment, in which:

16 is the carrier gas, 17 is gaseous hydrocarbons, 18 is mixing unit, 22 is the carrier gas with nano-particles, 28 is the melting chamber for the organo-metallic compound, 29 is dispenser, 30 is a melted organo-metallic compound, 31 is the channel of evaporation of the organo-metallic compound, 32 is a vapor of the organo-metallic substance, 33 is the decomposition channel for the organo-metallic compound.

In this unit for preparation of the reaction mixture to obtain a nano-particulate comprising the catalyst substance, solid organo-metallic compounds are used. Initial solid organo-metallic compound, e.g., ferrocene (Fe(C₅H₅)₂) is melted in the melting chamber 28, in which the temperature required for melting is provided by heaters. From the melting chamber the melted organo-metallic compound 30 enters the evaporation channel 31 through the dispenser 29, which allows for adjusting the feed rate of the substance. The melting chamber can be configured as a syringe. In this case, it further performs the function of the dispenser. Melting occurs in the syringe when the substance is heated to an appropriate temperature by a heater. Dosing occurs at a uniform movement of the syringe piston, whereby the melted substance is extruded into the evaporation channel 31. In the evaporation channel 31, the melted organo-metallic compound is heated to boiling by the heaters.

Vapor of the organo-metallic substance 32 are formed in the process of boiling. This vapor enters the decomposition channel 33 where it is mixed with the hot carrier gas 16. The evaporation and decomposition channels can be configured integrally. In this case, the evaporation and the decomposition channel is provided with an inlet for the carrier gas. In the decomposition channel, the temperature is maintained not lower than the decomposition temperature of the organo-metallic substance. The temperature in the channel is maintained by the heaters.

The temperature of the carrier gas entering the chamber is 600-1400° C. In the atmosphere of the carrier gas, the organo-metallic compound is decomposed, and the decomposition products comprising the catalyst substance are condensed in the nano-particles, for example, formed by the decomposition of ferrocene nano-particles containing iron. The carrier gas containing the nano-particles 22 further passes to the mixing unit where it is mixed with the preheated gaseous hydrocarbons. The resulting working mixture 2 enters the reaction chamber where the processes described above take place.

This unit for preparing the working mixture can be modified for liquid organo-metallic compounds. If liquid organo-metallic compounds are used, there is no need for a melting chamber, and the liquid organo-metallic compound is fed directly into the evaporation and the decomposition channel. The rest of the operations of preparation of the working mixture remain the same.

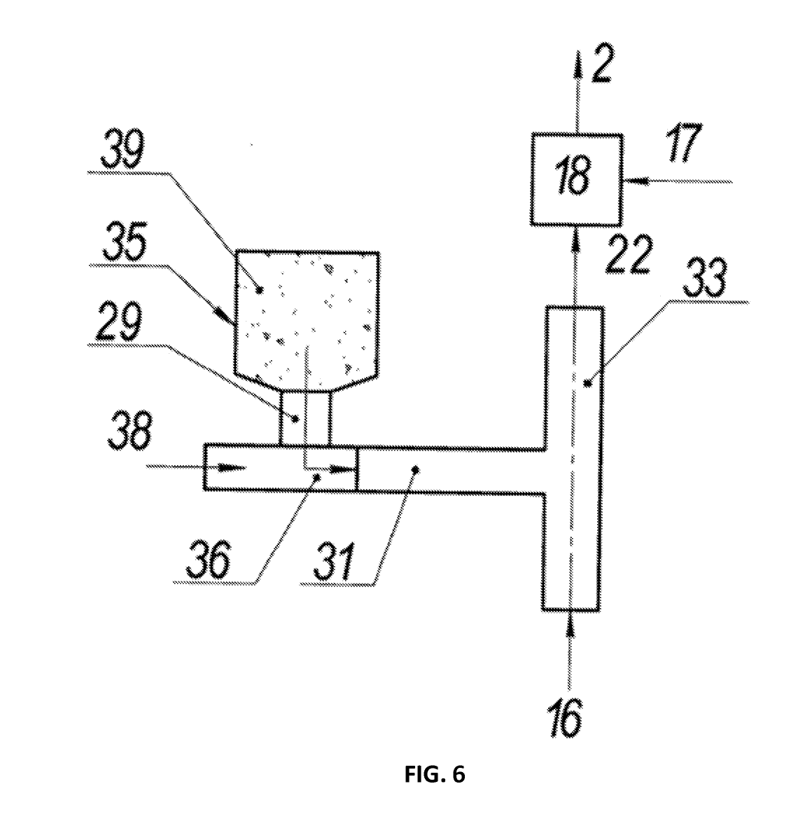

FIG. 6 illustrates a unit for preparing the working mixture according to the fifth embodiment, in which:

16 is the carrier gas, 17 is gaseous hydrocarbons, 18 is the mixing unit, 22 is the carrier gas with nano-particles, 29 is the dispenser, 31 is the evaporation channel for the organo-metallic compound, 33 is the decomposition channel for the organo-metallic compound, 35 is the container for the powder of the organo-metallic compound, 36 is the spraying channel for the organo-metallic compound, 38 is the spraying gas, 39 is the powder of the organo-metallic compound.

In this unit for preparation of the reaction mixture to obtain nano-particles comprising the catalyst substance, solid organo-metallic compounds in a form of a fine powder are used. The fine powder of the organo-metallic compound 39 is placed in the container 35. The powder from the container enters the spray channel 36 via the dispenser 29, through which the spraying gas 38 is passed spraying powder particles. The spraying gas preferably is an inert gas or the same gas as the carrier gas. The powder with the gas enters the evaporation channel 31 where it is heated and vaporized. Next, the powder vapors pass into the decomposition channel 33, through which the carrier gas 16 also passes.

In the decomposition channel, the organo-metallic compound decomposes due to the high temperatures of the channel walls and the heated carrier gas 16. After the decomposition of the organo-metallic substance in the carrier gas, the nano-particles containing the catalyst substance are condensed. The carrier gas with the nano-particles 22 enters the mixing unit 18, to which the gaseous hydrocarbons 17 are fed as well. The resulting working mixture 2 is then directed into the reaction chamber.

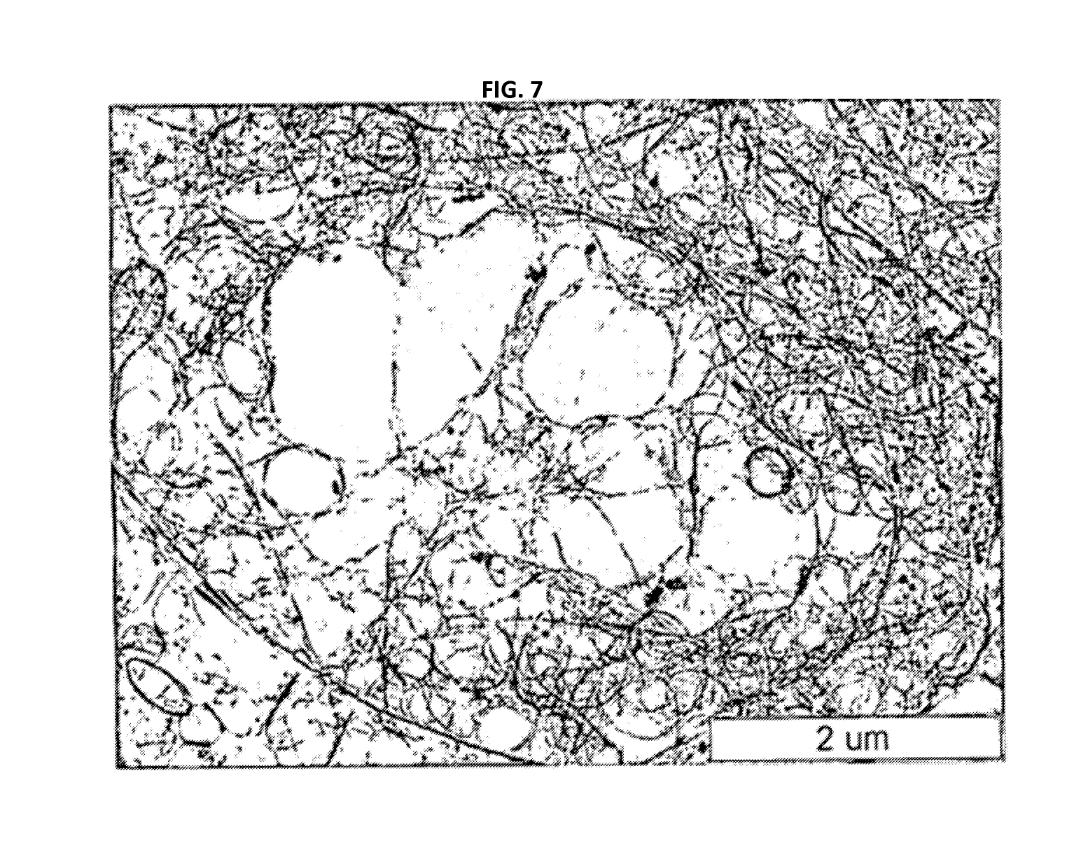

Liquid organo-metallic compounds can be used in the same way, but fine powder sprayed by gas is used instead of the liquid spray. The above embodiments of the unit for preparing the working mixture allow for obtaining the working mixture with nano-particles containing the catalyst substance with a mean size of not more than 100 nm, preferably 1-40 nm. It should be noted that the unit or an apparatus for preparing the working mixture can have other embodiments that are not described here. The carbon nano-structures obtained by the proposed method are illustrated in FIG. 7. They are of a good quality, low agglomeration, and can be produced on the industrial scale. It is also possible to control the process of their preparation.

Having thus described a preferred embodiment, it should be apparent to those skilled in the art that certain advantages of the described method and apparatus have been achieved. In particular, those skilled in the art would appreciate that the proposed system and method provide for efficient production of carbon nano-structures at low costs.

It should also be appreciated that various modifications, adaptations and alternative embodiments thereof may be made within the scope and spirit of the present invention. The invention is further defined by the following claims.

1-35. (canceled)

36. A method for producing carbon nano-structures by decomposition of hydrocarbon gases in a reaction chamber in a presence of a catalyst, the method comprising:
(a) supplying a working mixture containing nano-particles made of a catalyst substance, a carrier gas and gaseous hydrocarbons, wherein the nano-particles have an average size of less than 100 nm, and wherein the nano-particles are formed by condensation of a vapor or products of decomposition of chemical compounds of the catalyst substance;
(b) feeding the working mixture into a reaction chamber having a volume of at least 0.03 m³, and a distance between opposite walls or a diameter of at least 0.1 m;
(c) discharging carbon nano-structures from the reaction chamber in a gaseous flow containing gaseous hydrocarbon decomposition products; and
(d) separating the carbon nano-structures from the gaseous hydrocarbon decomposition products.

37. The method of claim 36, wherein a time of a residence of the working mixture inside the chamber is between 0.05 minutes to 100 minutes.

38. The method of claim 36, wherein the gaseous hydrocarbons are selected from any of:
natural gas;
methane;
ethane;
propane;
butane;
pentane;
hexane;
ethylene;
propylene;
aliphatic hydrocarbons;
hydrocarbons having a number of carbon atoms ranging from 1 to 10;
mono- or bicyclical aromatic hydrocarbons with insulated or fused-rings and olefins CₓH₂ₓ, wherein x is 2 or 3, or 4;
vapor of anthracene or anthracene oil;
a hydrocarbon having a high vapor pressure;
ethyl alcohol; and
a mixture of hydrocarbons.

39. The method of claim 36, wherein the catalyst substance is selected from transition metals of Group 5B, Group 6B, Group 8, iron, and a mixture of two, three, or more transition metals.

40. The method of claim 36, wherein the carrier gas is selected from any of an inert gas, hydrogen, nitrogen, ammonia, a hydrocarbon, an alcohol vapor, and a mixture of two, three or more thereof.

41. The method of claim 36, wherein the nano-particles comprising the catalyst substance include carbon nano-structure nuclears.

42. The method of claim 36, wherein the vapors containing the catalyst substance are produced in the evaporation chamber in a flow gas atmosphere by an electrically driven explosion of a wire formed of the catalyst substance, when passing through the wire an impulse of an electric current density of 10⁴ to 10⁷ A/mm².

43. The method of claim 42, wherein the flow gas is selected from any of an inert gas, a hydrocarbon, an alcohol vapor or a mixture of two, three or more thereof.

44. The method of claim 36, further comprising producing the working mixture by mixing the flow gas with the nano-particles containing the catalyst substance with gaseous hydrocarbons and mixing obtained mixture with the carrier gas, wherein the flow gas is an inert gas, nitrogen, a hydrocarbon, or a mixture thereof.

45. The method of claim 36, further comprising producing the working mixture by mixing the flow gas with the nano-particles containing the catalyst substance with a carrier gas and mixing this mixture with gaseous hydrocarbons, wherein the flow gas is an inert gas or nitrogen.

46. The method of claim 36, further comprising producing the working mixture by mixing the flow gas with nano-particles containing the catalyst substance with the carrier gas, wherein the flow gas is gaseous hydrocarbons or a mixture of hydrocarbons with an inert gas or nitrogen.

47. The method of claim 36, wherein the vapor containing the catalyst substance is prepared in an evaporation chamber by an electric arc discharge formed between two electrodes, wherein at least one of the electrodes is in a shape of an open container filled with metal containing the catalyst substance and the electrode is at least partially melted by the electric arc discharge.

48. The method of claim 36, wherein the vapors containing the catalyst substance are prepared in the evaporation chamber by an electric arc discharge formed between two electrodes, wherein each of the electrodes is in a form of an open container filled with a metal containing the catalyst substance and at least partially melted by the electric arc discharge and wherein the chamber is divided into two parts and each of the electrodes is located in a separate part of the two parts, and the two parts are interconnected through a discharge channel into which a plasma-forming gas is introduced in a form of a vortex flow.

49. The method of claim 363, wherein the plasma-forming gas is selected from any of a hydrocarbon gas, an inert gas, hydrogen, nitrogen, ammonia, or a mixture of at least two thereof.

50. The method according of claim 49, further comprising producing the working mixture by passing the carrier gas through the evaporation chamber and then mixing the carrier gas with the gaseous hydrocarbons.

51. The method of claim 36, further comprising producing the working mixture by vaporizing a liquid organo-metallic compound by heating the liquid organo-metallic compound at least to a boiling point and heating a produced vapor to at least a temperature of its decomposition.

52. The method of claim 36, further comprising producing the working mixture by melting a solid organo-metallic compound by heating the solid organo-metallic compound to its melting temperature, and then evaporating the organo-metallic compound by heating it to at least a boiling point, and heating the produced vapor to at least a temperature of its decomposition.

53. The method of claim 36, further comprising producing the working mixture by spraying an organo-metallic compound in a form of a fine powder with a spray gas and evaporating the organo-metallic compound by heating a resulting mixture at least up to a boiling point and decomposing the vapor by further heating at least to a temperature of its decomposition.

54. The method of claim 368, wherein the vapor of the organo-metallic compound is heated to its decomposition temperature by mixing it with the carrier gas that is heated to a temperature of 400-1400° C.

55. The method of claim 54, wherein the vapor of organo-metallic compound is pre-mixed with the gaseous hydrocarbons before being mixed with the carrier gas.

56. An apparatus for producing carbon nanostructures, the apparatus comprising:
a reaction chamber having an inlet for a working mixture and an outlet for gaseous hydrocarbon decomposition products;
means for preparing the working mixture;
nanoparticles formed of a catalyst substance provided to the reaction chamber;
a carrier gas provided to the reaction chamber;
gaseous hydrocarbons provided to the reaction chamber; and
a filter for separating carbon nanostructures from the gaseous hydrocarbon decomposition products,
wherein the reaction chamber has a volume of at least 0.03 m³ and a minimum distance between opposite walls of at least 0.1 m.

57. The apparatus of claim 56, wherein the means for preparing the working mixture comprises:
a vaporization chamber provided with a source of electrical impulse formed of a thin metal wire of a catalyst substance and placed in the vaporization chamber;
the wire configured to explode when an impulse of electric current having density of 10⁴-10⁷ A/mm² is passed through the wire; and
the vaporization chamber including an inlet for a flow gas and an outlet for the working mixture with nanoparticles containing the catalyst substance; and
at least one mixing unit for mixing the mixture with gaseous hydrocarbons or the carrier gas.

58. The apparatus of claim 56, wherein the means for preparing the working mixture comprises:
a vaporization chamber having two electrodes, one of the electrodes formed of a catalyst substance and configured to melt and vaporize due to an electric arc discharge between the two electrodes,
wherein the vaporization chamber includes an inlet for the carrier gas and an outlet for the mixture of the carrier gas with the nanoparticles containing the catalyst substance, and
wherein the vaporization chamber a mixing unit for mixing the carrier gas with the nanoparticles and the gaseous hydrocarbons.

59. The apparatus according to claim 58, wherein the electrode formed of the catalyst substance is in a shape of an open container filled with a metal containing the catalyst substance.

60. The apparatus of claim 56, wherein the means for preparing the working mixture comprises:
a vaporization chamber two electrodes, each of the two electrodes in a shape of an open container filled with a metal containing the catalyst substance;
each of the two electrodes configured to melt and vaporize due an electric arc discharge between the electrodes,
wherein the vaporization chamber is divided into two parts, with one electrode per part;
wherein the parts of the vaporization chamber are interconnected through a discharge channel,
wherein the discharge channel includes an inlet for a plasma forming gas, the inlet configured so that the plasma forming gas creates a vortex in the channel,
wherein the vaporization chamber includes an inlet for the carrier gas and an outlet for a mixture of the carrier gas and the nanoparticles; and
a mixing unit for mixing the carrier gas with the nanoparticles and the gaseous hydrocarbons.

61. The apparatus of claim 56, wherein the means for preparing the working mixture comprises a heated evaporation channel and a heated decomposition channel for an organo-metallic compound,
the means for preparing the working mixture further including an inlet for the carrier gas and an outlet for the carrier gas with the nanoparticles, and
a mixing unit for mixing the carrier gas with the nanoparticles and the gaseous hydrocarbons.

62. The apparatus of claim 61, wherein the outlet also lets out a vapor of the organo-metallic compound.

63. The apparatus according to claim 62, wherein the means for preparing the working mixture comprises a melting chamber for melting the organo-metallic compound, the melting chamber connected to the evaporation channel and configured for feeding the organo-metallic compound into the evaporation channel.

64. The apparatus of claim 56, wherein the means for preparing the working mixture comprises a container for a powder of an organo-metallic compound, the container connected via a dispenser to a spray channel for spraying the powder,
the channel coupled to an evaporation channel for evaporating the organo-metallic compound,
the evaporation channel connected to a decomposition channel of the organo-metallic compound,
the decomposition channel having an inlet for a carrier gas and an outlet for the carrier gas with the nanoparticles, and
a mixing unit for mixing the carrier gas and the nanoparticles with the gaseous hydrocarbons.

65. The apparatus of claim 56, wherein the reaction chamber includes a means for removing nanostructures deposited or formed on the walls of the reaction chamber.
